(19) United States
(12) Patent Application Publication
(10) Pub. No.: US 2017/0317174 A1
(43) Pub. Date: Nov. 2, 2017

(54) SILICON CARBIDE SUBSTRATE AND METHOD OF MANUFACTURING SILICON CARBIDE SUBSTRATE

(71) Applicant: Sumitomo Electric Industries, Ltd., Osaka-shi (JP)

(72) Inventor: Toru Hiyoshi, Osaka-shi (JP)

(21) Appl. No.: 15/531,950

(22) PCT Filed: Nov. 9, 2015
(86) PCT No.: PCT/JP2015/081438

§ 371 Date: May 31, 2017

(30) Foreign Application Priority Data
Jan. 21, 2015 (JP) 2015-009493

(51) Int. Cl. H01L 29/16; H01L 21/02; C30B 33/08; C23C 16/32; C30B 29/36; C30B 25/20; H01L 21/306

(52) U.S. Cl. CPC H01L 29/1608; H01L 21/30625; H01L 21/02529; H01L 21/02378; C23C 16/325; C30B 29/36; C30B 25/20; C30B 33/08

(57) ABSTRACT

A silicon carbide single-crystal substrate having a first main surface angled off relative to a {0001} plane, and a first peripheral edge provided continuously with the first main surface is prepared. A silicon carbide epitaxial layer is formed on the first main surface. The silicon carbide epitaxial layer has a second main surface in contact with the first main surface, a third main surface opposite to the second main surface, and a second peripheral edge provided continuously with each of the second main surface and the third main surface. A peripheral region including the first peripheral edge and the second peripheral edge is removed. The silicon carbide epitaxial layer has a thickness of not less than 50 μm in a direction perpendicular to the third main surface.

### TECHNICAL FIELD

The present invention relates to silicon carbide substrates and methods of manufacturing silicon carbide substrates.

### BACKGROUND ART

Owing to its high dielectric strength, silicon carbide has attracted attention as an alternative material to silicon for next-generation power semiconductor devices. Naoki Kaji and three others, “Ultrahigh-Voltage SiC PiN Diodes with an Improved Junction Termination Extension Structure and Enhanced Carrier Lifetime,” Japanese Journal of Applied Physics 52, 2013, 070204 (NPD 1) disclose a PiN diode in which an epitaxial layer has a thickness of 186 μm and the breakdown voltage exceeds 17 kV.

### CITATION LIST

### Non Patent Document

NPD 1: Naoki Kaji and three others, “Ultrahigh-Voltage SiC PiN Diodes with an Improved Junction Termination Extension Structure and Enhanced Carrier Lifetime,” Japanese Journal of Applied Physics 52, 2013, 070204

### SUMMARY OF INVENTION

### Technical Problem

However, during step-flow growth of a silicon carbide epitaxial layer on a silicon carbide single-crystal substrate, because a peripheral edge of the silicon carbide single-crystal substrate does not have and cannot transfer stacking information, stacking faults tend to extend from the peripheral edge toward a central portion of the substrate. Since stacking faults cause a device failure, a region of the silicon carbide epitaxial layer in which the stacking faults have been formed cannot be used for device formation. An increase in the region of the silicon carbide epitaxial layer in which the stacking faults have been formed results in a decrease in a region of the silicon carbide epitaxial layer that can be used for device formation (hereinafter also referred to as a device formation region).

An object of one embodiment of the present invention is to provide a silicon carbide substrate in which a device formation region can be effectively secured and a method of manufacturing a silicon carbide substrate.

### Solution to Problem

A method of manufacturing a silicon carbide substrate according to one embodiment of the present invention includes the following steps. A silicon carbide single-crystal substrate having a first main surface angled off relative to a {0001} plane, and a first peripheral edge provided continuously with the first main surface is prepared. A silicon carbide epitaxial layer is formed on the first main surface. The silicon carbide epitaxial layer has a second main surface in contact with the first main surface, a third main surface opposite to the second main surface, and a second peripheral edge provided continuously with each of the second main surface and the third main surface. A peripheral region including the first peripheral edge and the second peripheral edge is removed. The silicon carbide epitaxial layer has a thickness of not less than 50 μm in a direction perpendicular to the third main surface.

A silicon carbide substrate according to one embodiment of the present invention includes a silicon carbide single-crystal substrate and a silicon carbide epitaxial layer. The silicon carbide single-crystal substrate has a first main surface. The silicon carbide epitaxial layer is provided on the first main surface. The silicon carbide epitaxial layer has a second main surface in contact with the first main surface, a third main surface opposite to the second main surface, and a peripheral edge provided continuously with each of the second main surface and the third main surface. The silicon carbide epitaxial layer has a thickness of not less than 50 μm in a direction perpendicular to the third main surface. A stacking fault is not formed at a boundary between the peripheral edge and the third main surface.

### Advantageous Effects of Invention

According to one embodiment of the present invention, a silicon carbide substrate in which a device formation region can be effectively secured and a method of manufacturing a silicon carbide substrate can be provided.

### BRIEF DESCRIPTION OF DRAWINGS

FIG. 1 is a schematic sectional view showing the configuration of a silicon carbide substrate according to one embodiment of the present invention.

FIG. 2 is a schematic sectional view showing the configuration of a silicon carbide substrate according to a first variation of the embodiment of the present invention.

FIG. 3 is a schematic sectional view showing the configuration of a silicon carbide substrate according to a second variation of the embodiment of the present invention.

FIG. 4 is a flowchart schematically showing a method of manufacturing the silicon carbide substrate according to the embodiment of the present invention.

FIG. 5 is a schematic plan view showing a first step of the method of manufacturing the silicon carbide substrate according to the embodiment of the present invention.

FIG. 6 is a schematic sectional view showing the first step of the method of manufacturing the silicon carbide substrate according to the embodiment of the present invention.

FIG. 7 is a schematic plan view showing a second step of the method of manufacturing the silicon carbide substrate according to the embodiment of the present invention.

FIG. 8 is a schematic sectional view taken along line VIII-VIII in a direction of arrows in FIG. 7.

FIG. 9 is a schematic sectional view taken along line IX-IX in a direction of arrows in FIG. 7.

FIG. 10 is a schematic plan view showing a third step of the method of manufacturing the silicon carbide substrate according to the embodiment of the present invention.

FIG. 11 is a schematic sectional view showing the third step of the method of manufacturing the silicon carbide substrate according to the embodiment of the present invention.

FIG. 12 is a diagram showing a relationship between a width L of a stacking fault and the thickness of a silicon carbide epitaxial layer.

FIG. 13 is a schematic sectional view showing a fourth step of the method of manufacturing the silicon carbide substrate according to the embodiment of the present invention.

FIG. 14 is a schematic sectional view showing a variation of the third step of the method of manufacturing the silicon carbide substrate according to the embodiment of the present invention.

### DESCRIPTION OF EMBODIMENTS

### Description of Embodiment of the Present Invention

First, an embodiment of the present invention will be listed and described.

(1) A method of manufacturing a silicon carbide substrate 10 according to one embodiment of the present invention includes the following steps. A silicon carbide single-crystal substrate 11 having a first main surface 11a angled off relative to a {0001} plane, and a first peripheral edge 11c2 provided continuously with first main surface 11a is prepared. A silicon carbide epitaxial layer 12 is formed on first main surface 11a. Silicon carbide epitaxial layer 12 has a second main surface 12b in contact with first main surface 11a, a third main surface 12a opposite to second main surface 12b, and a second peripheral edge 12c2 provided continuously with each of second main surface 12b and third main surface 12a2. A peripheral region C including first peripheral edge 11c2 and second peripheral edge 12c2 is removed.

Silicon carbide epitaxial layer 12 has a thickness of not less than 50 μm in a direction perpendicular to third main surface 12a2.

In accordance with the method of manufacturing silicon carbide substrate 10 according to (1) above, stacking faults formed in peripheral region C in the step of forming silicon carbide epitaxial layer 12 can be removed. Consequently, the device formation region can be effectively secured. In accordance with the method of manufacturing silicon carbide substrate 10 according to (1) above, silicon carbide epitaxial layer 12 has a thickness of not less than 50 μm. Consequently, the device formation region can be effectively secured in silicon carbide substrate 10 including thick silicon carbide epitaxial layer 12 having a thickness of not less than 50 μm.

(2) In the method of manufacturing silicon carbide substrate 10 according to (1) above, after the removing peripheral region C, chemical mechanical polishing may be performed on third main surface 12a2. In the step of removing peripheral region C, silicon carbide epitaxial layer 12 may be damaged, causing step bunching and the like to take place on third main surface 12a2 of silicon carbide epitaxial layer 12 to roughen third main surface 12a2. By performing the chemical mechanical polishing on third main surface 12a2, the roughness of third main surface 12a2 can be reduced.

(3) In the method of manufacturing silicon carbide substrate 10 according to (1) or (2) above, in the preparing silicon carbide single-crystal substrate 11, a maximum diameter of first main surface 11a may be determined in consideration of a width of peripheral region C in a direction parallel to first main surface 11a. Consequently, silicon carbide substrate 10 of a desired size can be manufactured using silicon carbide single-crystal substrate 11 of an optimal size.

(4) In the method of manufacturing silicon carbide substrate 10 according to (3) above, assuming that an OFF angle of first main surface 11a is θ° and the thickness of silicon carbide epitaxial layer 12 is T μm, a width W1 may be not less than T/tan(θ) and not more than (T/tan(θ)) μm+10 mm. By calculating the width of the stacking fault based on the OFF angle of first main surface 11a and the thickness of silicon carbide epitaxial layer 12, a large device formation region can be secured while the amount of peripheral region C to be removed is minimized.

(5) In the method of manufacturing silicon carbide substrate 10 according to any one of (1) to (4) above, after the removing peripheral region C, a maximum diameter of third main surface 12a1 is not less than 100 mm. Consequently, a device formation region of not less than 100 mm can be secured.

(6) In the method of manufacturing silicon carbide substrate 10 according to any one of (1) to (5) above, silicon carbide epitaxial layer 12 may include an impurity capable of providing one of p type and n type. The impurity may have a concentration of not less than 1×10¹³ cm⁻³ and not more than 1×10¹⁶ cm⁻³. Consequently, a silicon carbide semiconductor device having a high breakdown voltage can be manufactured.

(7) In the method of manufacturing silicon carbide substrate 10 according to any one of (1) to (6) above, in the forming silicon carbide epitaxial layer 12, a stacking fault 2 may be formed in peripheral region C. In the removing peripheral region C, stacking fault 2 may be removed. Consequently, the device formation region can be secured.

(8) In the method of manufacturing silicon carbide substrate 10 according to any one of (1) to (7) above, in the forming silicon carbide epitaxial layer 12, a silicon carbide crystal 5 having a polytype different from a polytype of silicon carbide forming silicon carbide epitaxial layer 12 may be formed in peripheral region C. In the removing peripheral region C, silicon carbide crystal 5 may be removed. Peripheral region C of silicon carbide epitaxial layer 12, which dissipates more heat than a central region, tends to have a lower temperature. In peripheral region C, therefore, silicon carbide crystal 5 having a polytype different from the polytype of the silicon carbide forming silicon carbide epitaxial layer 12 tends to be formed. Silicon carbide crystal 5 having a different polytype may cause particles to be produced. The production of particles can be suppressed by removing silicon carbide crystal 5 having a different polytype.

(9) A silicon carbide substrate 10 according to one embodiment of the present invention includes a silicon carbide single-crystal substrate 11 and a silicon carbide epitaxial layer 12. Silicon carbide single-crystal substrate 11 has a first main surface 11a. Silicon carbide epitaxial layer 12 is provided on first main surface 11a. Silicon carbide epitaxial layer 12 has a second main surface 12b in contact with first main surface 11a, a third main surface 12a1 opposite to second main surface 12b, and aperipheral edge 12c1 provided continuously with each of second main surface 12b and third main surface 12a1. Silicon carbide epitaxial layer 12 has a thickness T1 of not less than 50 μm in a direction perpendicular to third main surface 12a1. A stacking fault is not formed at a boundary 12d1 between peripheral edge 12c1 and third main surface 12a1.

In accordance with silicon carbide substrate 10 according to (9) above, a stacking fault is not formed at boundary 12d1 between peripheral edge 12c1 and third main surface 12a1. Consequently, the device formation region can be effectively secured. In accordance with silicon carbide substrate 10 according to (9) above, silicon carbide epitaxial layer 12 has a thickness of not less than 50 μm.

Consequently, the device formation region can be effectively secured in silicon carbide substrate 10 including thick silicon carbide epitaxial layer 12 having a thickness of not less than 50 μm.

(10) In silicon carbide substrate 10 according to (9) above, a silicon carbide crystal 5 having a polytype different from a polytype of silicon carbide forming silicon carbide epitaxial layer 12 is not formed at peripheral edge 12c1. Peripheral region C of silicon carbide epitaxial layer 12, which dissipates more heat than the central region, tends to have a lower temperature. In peripheral region C, therefore, silicon carbide crystal 5 having a polytype different from the polytype of the silicon carbide forming silicon carbide epitaxial layer 12 tends to be formed. Silicon carbide crystal 5 having a different polytype may cause particles to be produced. In accordance with silicon carbide substrate 10 according to the embodiment, silicon carbide crystal 5 having a polytype different from the polytype of the silicon carbide forming silicon carbide epitaxial layer 12 is not formed at peripheral edge 12c1, so that the production of particles can be suppressed.

(11) In silicon carbide substrate 10 according to (9) or (10) above, a density of Z_{1/2} centers existing in the silicon carbide epitaxial layer may be not more than 5×10¹¹ cm⁻³. Consequently, a carrier lifetime can be improved.

(12) In silicon carbide substrate 10 according to any one of (9) to (11) above, a carrier lifetime may be not less than 1 microsecond. Consequently, the carrier lifetime can be improved. Consequently, when manufacturing a bipolar semiconductor device using this silicon carbide substrate 10, ON resistance can be reduced by the effect of conductivity modulation.

(13) In silicon carbide substrate 10 according to any one of (9) to (12) above, third main surface 12a1 may have a root mean square roughness of not more than 10 nm. Consequently, when manufacturing a MOSFET or IGBT, a gate oxide film can have improved reliability.

(14) In silicon carbide substrate 10 according to any one of (9) to (13) above, silicon carbide epitaxial layer 12 may include an impurity capable of providing one of p type and n type. The impurity may have a concentration of not less than 1×10¹³ cm ⁻³ and not more than 1×10¹⁶ cm⁻³. Consequently, a silicon carbide semiconductor device having a high breakdown voltage can be manufactured.

(15) In silicon carbide substrate 10 according to any one of (9) to (14) above, a density of basal plane dislocations 4 existing in silicon carbide epitaxial layer 12 may be not more than 10 cm⁻³. During use of a bipolar device manufactured using this silicon carbide substrate 10, stacking faults may occur due to basal plane dislocations 4, causing degradation of forward current characteristics. By setting the density of basal plane dislocations 4 existing in silicon carbide epitaxial layer 12 to not more than 10 cm⁻³, the degradation of forward current characteristics of the bipolar device can be suppressed.

### Details of Embodiment of the Present Invention

The embodiment of the present invention will be described below based on the drawings. It should be noted that the same or corresponding parts are designated by the same reference numbers in the following drawings, and description thereof will not be repeated. Regarding crystallographic indications in the present specification, an individual orientation is represented by [ ], a group orientation is represented by < >, an individual plane is represented by ( ) and a group plane is represented by { }. In addition, a negative crystallographic index is normally expressed by putting “-” (bar) above a numeral, but is expressed by putting a negative sign before the numeral in the present specification.

First, the configuration of a silicon carbide substrate 10 according to the embodiment is described.

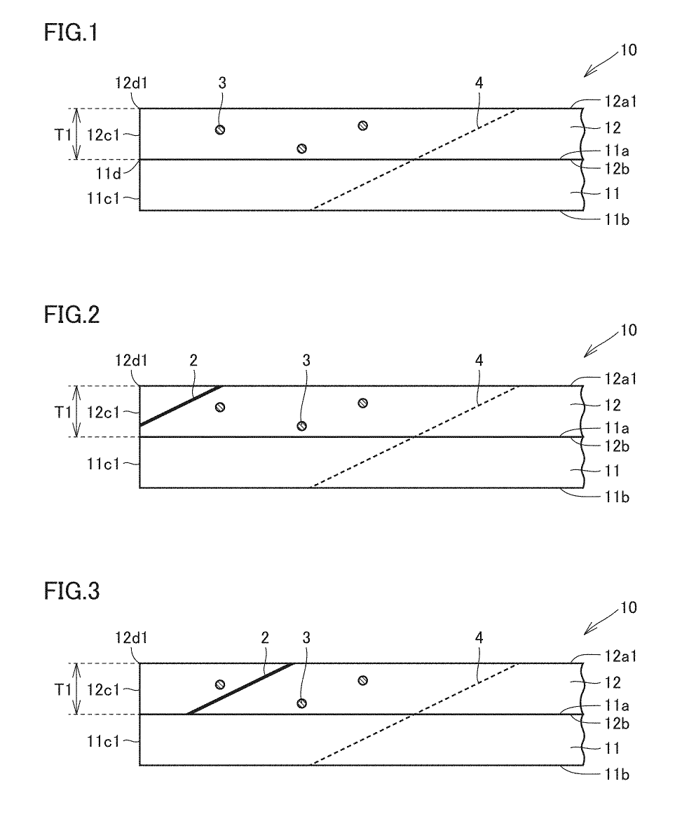

As shown in FIG. 1, silicon carbide substrate 10 according to the embodiment mainly has a silicon carbide single-crystal substrate 11 and a silicon carbide epitaxial layer 12. Silicon carbide single-crystal substrate 11 and silicon carbide epitaxial layer 12 are made of hexagonal silicon carbide having a polytype of 4H, for example. Silicon carbide single-crystal substrate 11 has a first main surface 11a, a fourth main surface 11b opposite to first main surface 11a, and a peripheral edge 11c1 provided continuously with each of first main surface 11a and fourth main surface 11b. Silicon carbide epitaxial layer 12 is provided on first main surface 11a. Silicon carbide epitaxial layer 12 has a second main surface 12b in contact with first main surface 11a, a third main surface 12a1 opposite to second main surface 12b, and a peripheral edge 12c1 provided continuously with each of second main surface 12b and third main surface 12a1. Peripheral edge 12c1 of silicon carbide epitaxial layer 12 may be provided along peripheral edge 11c1 of silicon carbide single-crystal substrate 11.

Silicon carbide epitaxial layer 12 has a thickness T1 of not less than 50 μm in a direction perpendicular to third main surface 12a1. Thickness T1 is preferably not less than 100 μm, more preferably not less than 150 μm, further preferably not less than 200 μm, and further preferably not less than 300 μm. Third main surface 12a1 has a root mean square roughness (Rq (RMS)) of not more than 10 nm, for example, and preferably not more than 5 nm. The root mean square roughness of third main surface 12a1 can be measured, for example, by means of an AFM (Atomic Force Microscope).

A plurality of Z_{1/2} centers 3 may exist in silicon carbide epitaxial layer 12. Z_{1/2} centers 3 are point defects caused by carbon vacancies. Each of Z_{1/2} centers 3 has an energy level of Ec (the lowest energy in the conduction band) −0.65 eV. A density of Z_{1/2} centers 3 existing in silicon carbide epitaxial layer 12 is not more than 5×10¹¹ cm⁻³, for example, and preferably not more than 2×10¹¹ cm ⁻³. The density of Z_{1/2} centers 3 can be measured, for example, by means of the DLTS (Deep Level Transient Spectroscopy) method. It should be noted that “the density of Z_{1/2} centers 3 is not more than 5×10¹¹ cm⁻³” means that the average value of the density of Z_{1/2} centers 3 is not more than 5×10¹¹ cm⁻³. The density of Z_{1/2} centers 3 is calculated, for example, by measuring ten arbitrary regions in silicon carbide epitaxial layer 12 by means of DLTS, and then determining an average value of the densities of Z_{1/2} centers 3 in the ten regions.

A plurality of basal plane dislocations 4 may exist in silicon carbide epitaxial layer 12. Basal plane dislocations 4 are dislocations extending in a {0001} plane. A density of basal plane dislocations 4 existing in silicon carbide epitaxial layer 12 may be not more than 10 cm³. The density of basal plane dislocations 4 can be measured, for example, by means of the photoluminescence method. Basal plane dislocations 4 may be included in silicon carbide single-crystal substrate 11. Basal plane dislocations 4 may extend from silicon carbide single-crystal substrate 11 to silicon carbide epitaxial layer 12.

Silicon carbide epitaxial layer 12 may include an impurity capable of providing one of p type and n type. The impurity capable of providing p type is aluminum or boron, for example. The impurity capable of providing n type is nitrogen or phosphorus, for example. This impurity has a concentration of not less than 1×10¹³ cm⁻³ and not more than 1×10¹⁶ cm⁻³, for example. For example, in order to realize a power semiconductor having a breakdown voltage of 6.5 kV, silicon carbide epitaxial layer 12 has a thickness of about not less than 50 μm and not more than 60 μm, and includes nitrogen at a concentration of about not less than 5×10¹⁴ cm⁻³ and not more than 3×10¹⁵ cm⁻³. For example, in order to realize a power semiconductor having a breakdown voltage of 10 kV, silicon carbide epitaxial layer 12 has a thickness of about not less than 80 μm and not more than 120 μm, and includes nitrogen at a concentration of about not less than 1×10¹⁴ cm⁻³ and not more than 1×10¹⁵ cm⁻³. For example, in order to realize a power semiconductor having a breakdown voltage of 30 kV, silicon carbide epitaxial layer 12 has a thickness of about 300 μm, and includes nitrogen at a concentration of about not less than 5×10¹³ cm ⁻³ and not more than 5×10¹⁴ cm ⁻³. Silicon carbide epitaxial layer 12 may include nitrogen at a concentration of not less than 5×10¹³ cm⁻³ and not more than 1×10¹⁵ cm⁻³, or not less than 1×10¹⁴ cm⁻³ and not more than 7×10¹⁴ cm⁻³.

Silicon carbide single-crystal substrate 11 may include an impurity capable of providing one of p type and n type. Preferably, the concentration of the impurity included in silicon carbide single-crystal substrate 11 is higher than the concentration of the impurity included in silicon carbide epitaxial layer 12. The types and concentrations of the impurities included in silicon carbide single-crystal substrate 11 and silicon carbide epitaxial layer 12 can be measured, for example, by means of SIMS (Secondary Ion Mass Spectrometry).

A carrier lifetime is preferably not less than 1 microsecond, and more preferably not less than 1.5 microseconds. A typical carrier lifetime is not more than 0.9 microseconds, for example. The carrier lifetime may be not more than 25 microseconds, for example. The carrier lifetime can be measured, for example, by means of the μ-PCD (Microwave Photo Conductivity Decay) method. According to the μ-PCD method, the carrier lifetime is determined by generating excess carriers by application of pulse light to silicon carbide epitaxial layer 12, and measuring conductivity, which is decreased according to recombination of the excess carriers, based on reflectance of microwave.

Preferably, a silicon carbide crystal having a polytype different from the polytype of the silicon carbide forming silicon carbide epitaxial layer 12 is not formed at peripheral edge 12c1. For example, in the case where the silicon carbide forming silicon carbide single-crystal substrate 11 and silicon carbide epitaxial layer 12 has a polytype of 4H, a silicon carbide crystal having a polytype of 3C or 6H is not formed at peripheral edge 12c1. Stated another way, the polytype of the silicon carbide forming peripheral edge 12c1 of silicon carbide epitaxial layer 12 is the same as the polytype of the silicon carbide forming third main surface 12a1. For example, in the case where the silicon carbide forming third main surface 12a1 has a polytype of 4H, the silicon carbide forming peripheral edge 12c1 also has a polytype of 4H. It should be noted that the type of a polytype can be identified, for example, by means of Raman spectroscopy.

As shown in FIG. 1, a stacking fault is not formed at a boundary 12d1 between peripheral edge 12c1 and third main surface 12a1 of silicon carbide epitaxial layer 12.

Stated another way, a stacking fault is not formed at edge 12d1 of the uppermost surface of silicon carbide epitaxial layer 12 which is seen when silicon carbide epitaxial layer 12 is viewed along a direction perpendicular to second main surface 12b. It can be determined whether or not a stacking fault has been formed, for example, by means of the photoluminescence method. Specifically, by setting the wavelength of excitation light to 313 nm, and taking an image using a band-pass filter having a wavelength of 390 nm, it is determined that a stacking fault has been formed when light emission occurs due to a stacking fault, and it is determined that a stacking fault has not been formed when light emission due to a stacking fault is not detected.

As shown in FIGS. 2 and 3, it is only required that a stacking fault 2 not be formed at boundary 12d1 between peripheral edge 12c1 and third main surface 12a1, and stacking fault 2 may be formed in silicon carbide epitaxial layer 12. As shown in FIG. 2, stacking fault 2 may extend from peripheral edge 12c1 to third main surface 12a1. Stated another way, stacking fault 2 may be exposed at both peripheral edge 12c1 and third main surface 12a1. Stacking fault 2 may be formed in silicon carbide epitaxial layer 12 such that it is spaced from boundary 12d1. As shown in FIG. 3, stacking fault 2 may extend from second main surface 12b to third main surface 12a1. Stated another way, stacking fault 2 may be exposed at both second main surface 12b and third main surface 12a1.

Next, a method of manufacturing silicon carbide substrate 10 according to the embodiment is described.

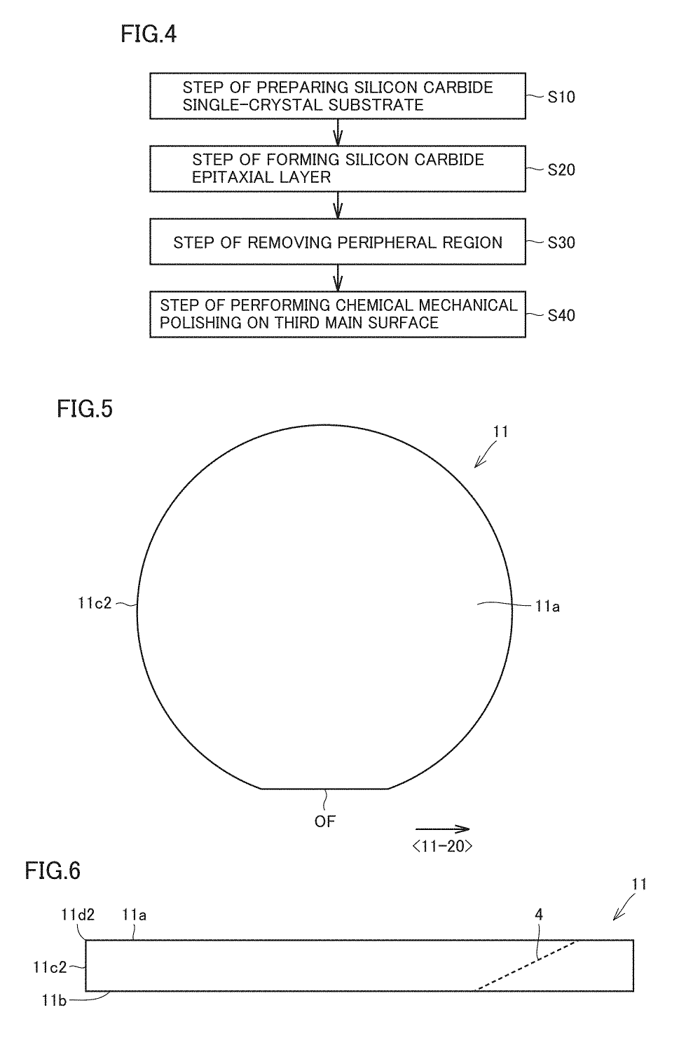

First, a step of preparing a silicon carbide single-crystal substrate (S10: FIG. 4) is performed. For example, silicon carbide single-crystal substrate 11 is prepared by slicing a silicon carbide single-crystal ingot. The silicon carbide has a polytype of 4H, for example. As shown in FIGS. 5 and 6, silicon carbide single-crystal substrate 11 has first main surface 11a, a first peripheral edge 11c2 provided continuously with first main surface 11a, and fourth main surface 11b provided continuously with first peripheral edge 11c2. Fourth main surface 11b is a surface opposite to first main surface 11a. First main surface 11a is a plane angled off by an OFF angle relative to the {0001} plane. The OFF angle is not less than 1° and not more than 8°, for example. The OFF direction is a <11-20> direction, for example.

As shown in FIG. 5, first main surface 11a is substantially circular in plan view (in a field of view seen along a direction perpendicular to first main surface 11a). Silicon carbide single-crystal substrate 11 may be provided with an orientation flat OF. Orientation flat OF extends along the <11-20> direction, for example. Silicon carbide single-crystal substrate 11 includes an impurity capable of providing n type, such as nitrogen. Basal plane dislocations 4 may be formed in silicon carbide single-crystal substrate 11. In this manner, silicon carbide single-crystal substrate 11 having first main surface 11a angled off relative to the {0001} plane, first peripheral edge 11c2 provided continuously with first main surface 11a, and fourth main surface 11b provided continuously with first peripheral edge 11c2 is prepared (see FIG. 6).

Next, a step of forming a silicon carbide epitaxial layer (S20: FIG. 4) is performed. Silicon carbide epitaxial layer 12 is epitaxially grown on silicon carbide single-crystal substrate 11 by the CVD (Chemical Vapor Deposition) method, for example. For the epitaxial growth, silane (SiH₄) and propane (C₃H₈) are employed as a source material gas, whereas hydrogen (H₂) is employed as a carrier gas. The temperature of silicon carbide single-crystal substrate 11 during the epitaxial growth is about not less than 1400° C. and not more than 1700° C. In this manner, silicon carbide epitaxial layer 12 is formed on first main surface 11a of silicon carbide single-crystal substrate 11. Silicon carbide epitaxial layer 12 has second main surface 12b in contact with first main surface 11a of silicon carbide single-crystal substrate 11, a third main surface 12a2 opposite to second main surface 12b, and a second peripheral edge 12c2 provided continuously with each of second main surface 12b and third main surface 12a2 (see FIGS. 8 and 9).

Preferably, the silicon carbide epitaxial layer includes an impurity capable of providing one of p type and n type. This impurity has a concentration of not less than 1×10¹³ cm⁻³ and not more than 1×10¹⁶ cm⁻³, for example, preferably not less than 5×10¹³ cm⁻³ and not more than 1×10¹⁵ cm⁻³, and more preferably not less than 1×10¹⁴ cm⁻³ and not more than 7×10¹⁴ cm⁻³. Silicon carbide epitaxial layer 12 has a thickness T1 of not less than 50 μm in a direction perpendicular to third main surface 12a. The lower limit of thickness T1 may be 100 μm, 150 μm, 200 μm, or 300 μm. The upper limit of thickness T1 may be 500 μm. By setting the upper limit to 500 μm, a final film thickness depending on the breakdown voltage can be optionally selected. The plurality of Z_{1/2} centers 3 may exist in silicon carbide epitaxial layer 12. The density of Z_{1/2} centers 3 existing in silicon carbide epitaxial layer 12 is not more than 5×10¹¹ cm⁻³, for example.

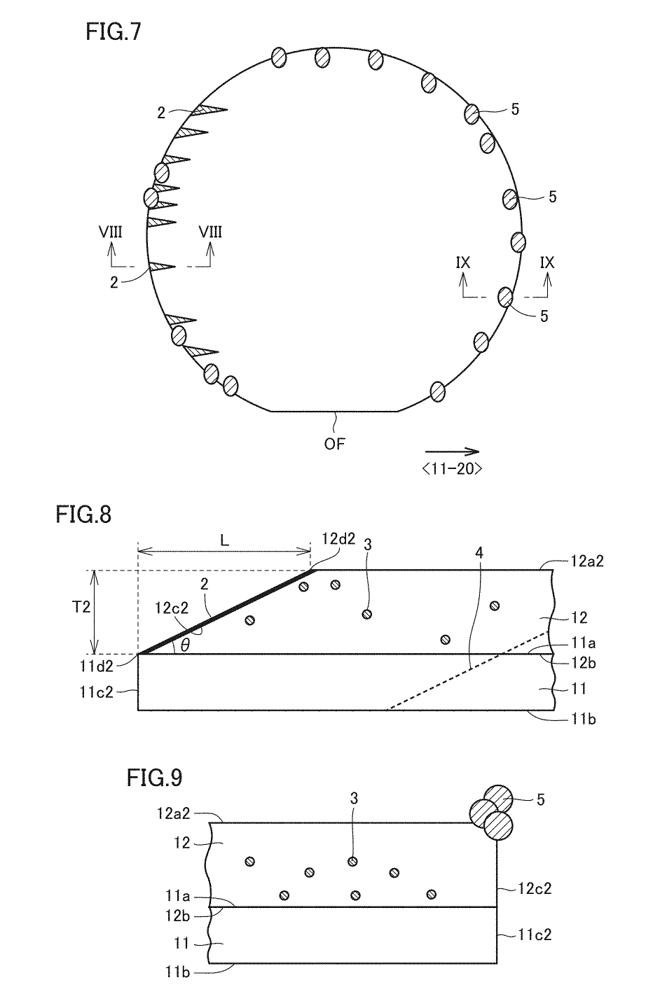

As shown in FIG. 7, in the step of forming silicon carbide epitaxial layer 12, stacking faults 2 are formed in a peripheral region of silicon carbide epitaxial layer 12. Stacking faults 2 are formed in the vicinity of second peripheral edge 12c2 of silicon carbide epitaxial layer 12 facing opposite to the OFF direction (direction of an arrow in FIG. 7), while very few stacking faults 2 are formed in the vicinity of second peripheral edge 12c2 facing the OFF direction. Stacking faults 2 extend along the OFF direction from second peripheral edge 12c2 facing opposite to the OFF direction toward the center of silicon carbide epitaxial layer 12. The width of each stacking fault 2 in a direction parallel to third main surface 12a2 may decrease in a direction facing the OFF direction.

As shown in FIG. 8, silicon carbide epitaxial layer 12 receives stacking information transferred from first main surface 11a of silicon carbide single-crystal substrate 11, and step-flow growth of silicon carbide epitaxial layer 12 takes place. A plane forming second peripheral edge 12c2 is the {0001} plane. Since an edge 11d2 of first main surface 11a does not have stacking information, stacking fault 2 tends to be formed on second peripheral edge 12c2 with edge 11d2 as a starting point. That is, stacking fault 2 tends to be formed in the peripheral region. Stacking fault 2 is formed to extend from edge 11d2 of first main surface 11a of silicon carbide single-crystal substrate 11 to a boundary 12d2 between second peripheral edge 12c2 and third main surface 12a2 of silicon carbide epitaxial layer 12. In FIG. 8, an angle θ is the same angle as the OFF angle of first main surface 11a.

As shown in FIG. 7, in the step of forming silicon carbide epitaxial layer 12, silicon carbide crystals 5 having a polytype (different type of polytype) different from the polytype of the silicon carbide forming silicon carbide epitaxial layer 12 may be formed in the peripheral region. In the case where the silicon carbide forming silicon carbide epitaxial layer 12 has a polytype of 4H, silicon carbide crystals 5 have a polytype of 3C or 6H, for example. In the peripheral region of silicon carbide single-crystal substrate 11, which tends to have a temperature lower than that of the other portion of silicon carbide single-crystal substrate 11, silicon carbide crystals 5 having a different type of polytype tend to be formed. Unlike stacking faults 2, silicon carbide crystals 5 are formed in the vicinity of second peripheral edge 12c2 facing the OFF direction as well.

As shown in FIGS. 7 and 8, each silicon carbide crystal 5 is a granular mass, for example. Silicon carbide crystals 5 are formed, for example, in the vicinity of the position where a plane extending along second peripheral edge 12c2 and a plane extending along third main surface 12a2 intersect each other. Silicon carbide crystals 5 may be formed to be spaced from second main surface 12b while being in contact with second peripheral edge 12c2 and third main surface 12a2.

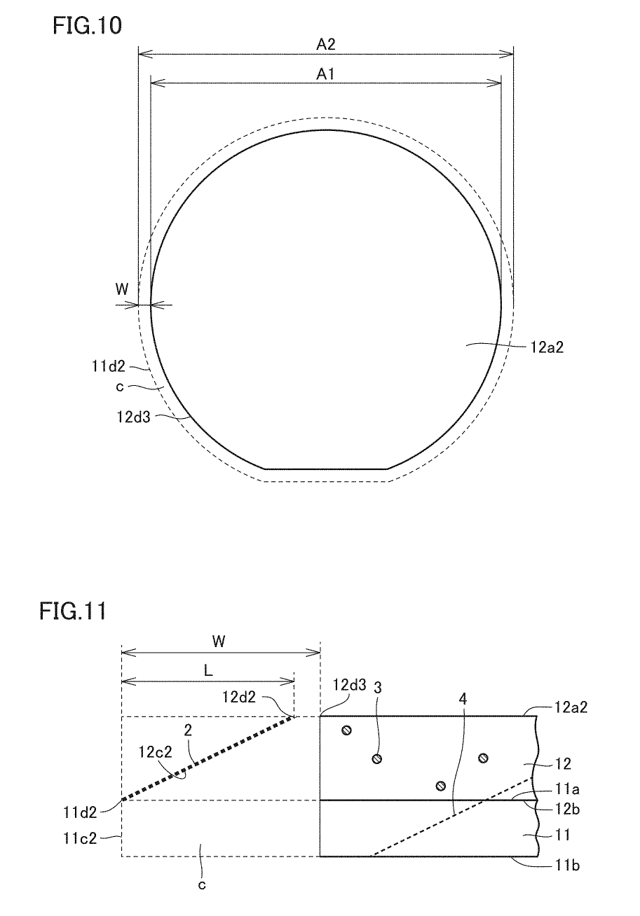

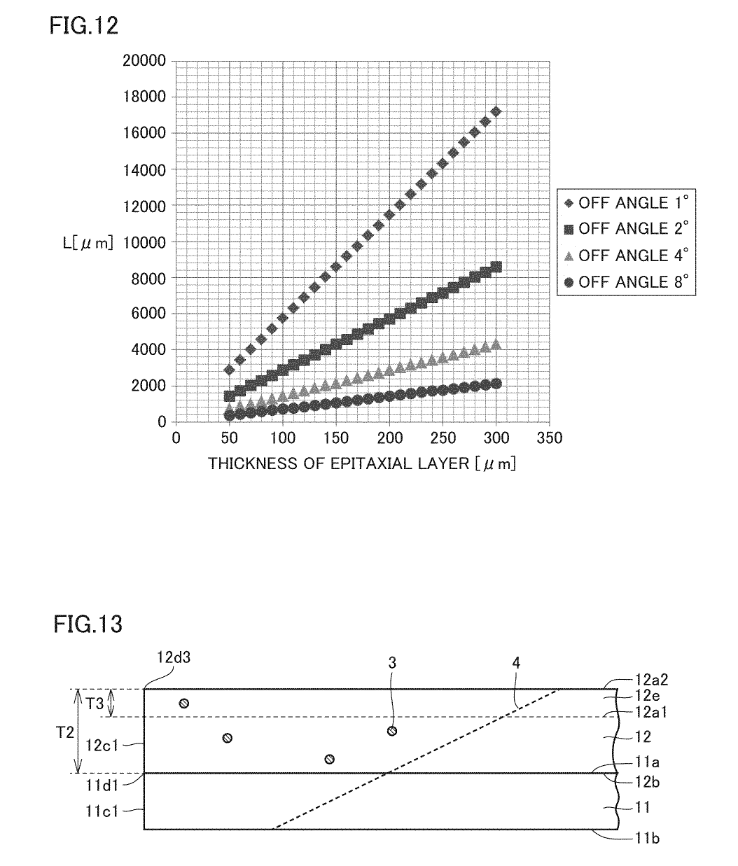

Next, a step of removing the peripheral region (S30: FIG. 4) is performed. As shown in FIGS. 10 and 11, a peripheral region C including first peripheral edge 11c2 and second peripheral edge 12c2 is removed. Peripheral region C includes a peripheral region of silicon carbide single-crystal substrate 11 which includes first peripheral edge 11c2, and a peripheral region of silicon carbide epitaxial layer 12 which includes second peripheral edge 12c2. The removal of peripheral region C may be performed, for example, by means of a wire saw, laser processing, or polishing. Preferably, in the step of removing peripheral region C, stacking faults 2 that have been formed in peripheral region C are removed. Preferably, in the step of removing peripheral region C, silicon carbide crystals 5 that have been formed in peripheral region C are removed. As a result of the removal of peripheral region C, the edge of the silicon carbide substrate is now an edge 12d3 instead of edge 11d2. The entire circumference of silicon carbide single-crystal substrate 11 and the entire circumference of silicon carbide epitaxial layer 12 may be removed such that the silicon carbide substrate is substantially circular in plan view after the step of removing peripheral region C. Peripheral region C may be removed such that the silicon carbide substrate is provided with orientation flat OF. Peripheral region C may be removed such that the silicon carbide substrate has a shape conforming to the process after the step of removing peripheral region C. The step of removing the peripheral region may result in processing damage to silicon carbide epitaxial layer 12, causing step bunching to be formed on third main surface 12a2 of silicon carbide epitaxial layer 12.

Next, a method of determining a width W of peripheral region C to be removed is described. FIG. 12 shows a relationship between width L of stacking fault 2 in a direction parallel to first main surface 11a (see FIG. 11) and the thickness of silicon carbide epitaxial layer 12. In FIG. 12, a rhombus, a square, a triangle and a circle indicate that the OFF angle of first main surface 11a is 1°, 2°, 4° and 8°, respectively. Width L of stacking fault 2 is determined based on the thickness of silicon carbide epitaxial layer 12 and the OFF angle of first main surface 11a. As shown in FIG. 12, width L of stacking fault 2 increases as the thickness of silicon carbide epitaxial layer 12 increases. Width L of stacking fault 2 increases as the OFF angle decreases. The OFF angle of first main surface 11a is not less than 1° and not more than 8°, for example. The smaller the OFF angle, the greater the width L of the stacking fault, and thus the more advantageous it is to employ the manufacturing method according to the present embodiment. On the other hand, the greater the OFF angle, the smaller the width of peripheral region C to be removed. In other words, a greater OFF angle is preferred from the standpoint of securing a large device formation region.

Preferably, in the step of preparing the silicon carbide single-crystal substrate (S10: FIG. 4), a maximum diameter A2 of first main surface 11a is determined in consideration of the width of peripheral region C in the direction parallel to first main surface 11a. Specifically, width L of stacking fault 2 is calculated in consideration of the thickness of silicon carbide epitaxial layer 12 and the OFF angle of first main surface 11a. Then, maximum diameter A2 of first main surface 11a may be determined such that it is greater by twice the width L of stacking fault 2 than an ultimately required maximum diameter A1 of silicon carbide substrate 10.

Assuming that the OFF angle of first main surface 11a is θ° and the thickness of silicon carbide epitaxial layer 12 is T μm, width W of peripheral region C to be removed is not less than T2/tan(θ) μm and not more than (T/tan(θ)) μm+10 mm, for example. Preferably, width W is not less than T/tan(θ) μm and not more than (T/tan(θ)) μm+5 mm. Preferably, after the step of removing peripheral region C, maximum diameter A1 of third main surface 12a2 of silicon carbide epitaxial layer 12 is not less than 100 mm. Maximum diameter A1 may be not less than 75 mm, not less than 150 mm, or not less than 200 mm. Before the step of removing peripheral region C, maximum diameter A2 of third main surface 12a2 of silicon carbide epitaxial layer 12 may be 120 mm, for example. After the step of removing peripheral region C, maximum diameter A1 of third main surface 12a2 of silicon carbide epitaxial layer 12 may be 100 mm, for example.

Next, a step of performing chemical mechanical polishing on the third main surface (S40: FIG. 4) may be performed. For example, chemical mechanical polishing (CMP) is performed on third main surface 12a2 of silicon carbide epitaxial layer 12, to remove a surface layer 12e including third main surface 12a2. Third main surface 12a1 of silicon carbide epitaxial layer 12 is thereby exposed. Colloidal silica is used, for example, as a slurry of the CMP. By performing the CMP, the step bunching that has been formed on third main surface 12a2 may be removed. By performing the CMP, some of Z_{1/2} center 3 and some of basal plane dislocations 4 included in silicon carbide epitaxial layer 12 may be removed. A thickness T2 of silicon carbide epitaxial layer 12 may be determined in consideration of a thickness T3 of surface layer 12e along the direction perpendicular to third main surface 12a2. Silicon carbide substrate 10 shown in FIG. 1 is thereby completed.

It should be noted that although n type has been described as the first conductivity type and p type as the second conductivity type in the above embodiment, p type may be the first conductivity type and n type may be the second conductivity type.

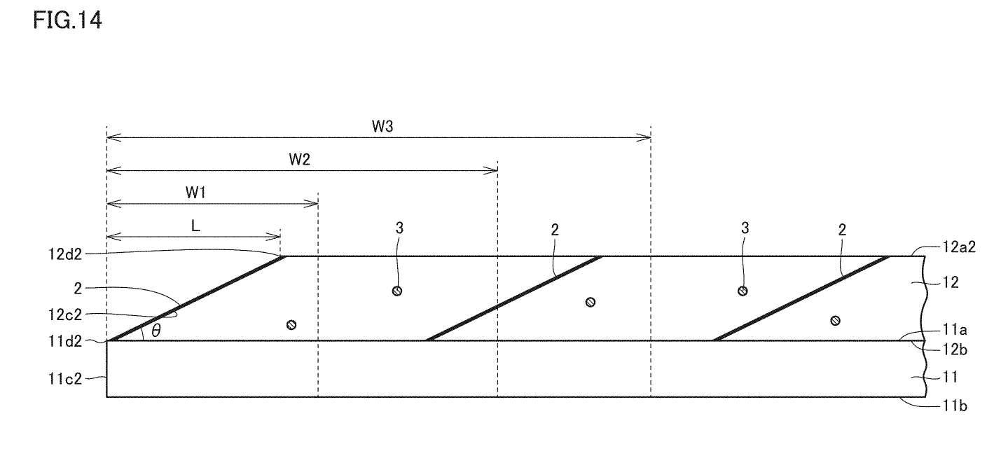

Next, a variation of the step of removing the peripheral region is described. As shown in FIG. 14, after the step of forming the silicon carbide epitaxial layer, stacking faults 2 may be formed in silicon carbide epitaxial layer 12. Each stacking fault 2 may extend from a position on first main surface 11a spaced from edge 11d2 of silicon carbide single-crystal substrate 11. In the step of removing the peripheral region (S30: FIG. 4), if the width of peripheral region C to be removed is a width W2, stacking fault 2 is exposed at both peripheral edge 12c1 and third main surface 12a1 of silicon carbide epitaxial layer 12 after the step of removing the peripheral region (see FIG. 2). If the width of peripheral region C to be removed is a width W3, stacking fault 2 is exposed at both second main surface 12b and third main surface 12a1 of silicon carbide epitaxial layer 12 after the step of removing the peripheral region (see FIG. 3). Silicon carbide substrate 10 shown in FIGS. 2 and 3 may be manufactured by the removal of peripheral region C as described above.

Next, the function and effect of silicon carbide substrate 10 and the method of manufacturing the same according to the embodiment will be described.

In accordance with the method of manufacturing silicon carbide substrate 10 according to the embodiment, the stacking faults formed in peripheral region C in the step of forming silicon carbide epitaxial layer 12 can be removed. Consequently, the device formation region can be effectively secured. In accordance with the method of manufacturing silicon carbide substrate 10 according to the embodiment, silicon carbide epitaxial layer 12 has a thickness of not less than 50 Consequently, the device formation region can be effectively secured in silicon carbide substrate 10 including thick silicon carbide epitaxial layer 12 having a thickness of not less than 50 μm.

In accordance with the method of manufacturing silicon carbide substrate 10 according to the embodiment, after the step of removing peripheral region C, chemical mechanical polishing may be performed on third main surface 12a2. In the step of removing peripheral region C, silicon carbide epitaxial layer 12 may be damaged, causing step bunching and the like to take place on third main surface 12a2 of silicon carbide epitaxial layer 12 to roughen third main surface 12a2. By performing the chemical mechanical polishing on third main surface 12a2, the roughness of third main surface 12a2 can be reduced.

Moreover, in accordance with the method of manufacturing silicon carbide substrate 10 according to the embodiment, in the step of preparing silicon carbide single-crystal substrate 11, the maximum diameter of first main surface 11a may be determined in consideration of the width of peripheral region C in the direction parallel to first main surface 11a. Consequently, silicon carbide substrate 10 of a desired size can be manufactured using silicon carbide single-crystal substrate 11 of an optimal size.

Moreover, in accordance with the method of manufacturing silicon carbide substrate 10 according to the embodiment, assuming that the OFF angle of first main surface 11a is θ° and the thickness of silicon carbide epitaxial layer 12 is T μm, width W1 may be not less than T/tan(θ) μm and not more than (T/tan(θ)) μm+10 mm. By calculating the width of the stacking fault based on the OFF angle of first main surface 11a and the thickness of silicon carbide epitaxial layer 12, a large device formation region can be secured while the amount of peripheral region C to be removed is minimized.

Moreover, in accordance with the method of manufacturing silicon carbide substrate 10 according to the embodiment, after the step of removing peripheral region C, the maximum diameter of third main surface 12a1 is not less than 100 mm. Consequently, a device formation region of not less than 100 mm can be secured.

Moreover, in accordance with the method of manufacturing silicon carbide substrate 10 according to the embodiment, silicon carbide epitaxial layer 12 may include an impurity capable of providing one of p type and n type. The impurity may have a concentration of not less than 1×10¹³ cm⁻³ and not more than 1×10¹⁶ cm⁻³. Consequently, a silicon carbide semiconductor device having a high breakdown voltage can be manufactured.

Moreover, in accordance with the method of manufacturing silicon carbide substrate 10 according to the embodiment, in the step of forming silicon carbide epitaxial layer 12, stacking faults 2 may be formed in peripheral region C. In the step of removing peripheral region C, stacking faults 2 may be removed. Consequently, the device formation region can be secured.

Moreover, in accordance with the method of manufacturing silicon carbide substrate 10 according to the embodiment, in the step of forming silicon carbide epitaxial layer 12, silicon carbide crystals 5 having a polytype different from the polytype of the silicon carbide forming silicon carbide epitaxial layer 12 may be formed in peripheral region C. In the step of removing peripheral region C, silicon carbide crystals 5 may be removed. Peripheral region C of silicon carbide epitaxial layer 12, which dissipates more heat than a central region, tends to have a lower temperature. In peripheral region C, therefore, silicon carbide crystals 5 having a polytype different from the polytype of the silicon carbide forming silicon carbide epitaxial layer 12 tend to be formed. Silicon carbide crystals 5 having a different polytype may cause particles to be produced. The production of particles can be suppressed by removing silicon carbide crystals 5 having a different polytype.

In accordance with silicon carbide substrate 10 according to the embodiment, stacking faults are not formed at boundary 12d1 between peripheral edge 12c1 and third main surface 12a1. Consequently, the device formation region can be effectively secured. In accordance with silicon carbide substrate 10 according to the embodiment, silicon carbide epitaxial layer 12 has a thickness of not less than 50 μm. Consequently, the device formation region can be effectively secured in silicon carbide substrate 10 including thick silicon carbide epitaxial layer 12 having a thickness of not less than 50 μm.

In accordance with silicon carbide substrate 10 according to the embodiment, silicon carbide crystals 5 having a polytype different from the polytype of the silicon carbide forming silicon carbide epitaxial layer 12 are not formed at peripheral edge 12c1. Peripheral region C of silicon carbide epitaxial layer 12, which dissipates more heat than the central region, tends to have a lower temperature. In peripheral region C, therefore, silicon carbide crystals 5 having a polytype different from the polytype of the silicon carbide forming silicon carbide epitaxial layer 12 tend to be formed. Silicon carbide crystals 5 having a different polytype may cause particles to be produced. In accordance with silicon carbide substrate 10 according to the embodiment, silicon carbide crystals 5 having a polytype different from the polytype of the silicon carbide forming silicon carbide epitaxial layer 12 are not formed at peripheral edge 12c1, so that the production of particles can be suppressed.

Moreover, in accordance with silicon carbide substrate 10 according to the embodiment, the density of Z_{1/2} centers existing in silicon carbide epitaxial layer 12 may be not more than 5×10¹¹ cm⁻³. Consequently, the carrier lifetime can be improved.

Moreover, in accordance with silicon carbide substrate 10 according to the embodiment, the carrier lifetime may be not less than 1 microsecond. Consequently, the carrier lifetime can be improved. Consequently, when manufacturing a bipolar semiconductor device using this silicon carbide substrate 10, ON resistance can be reduced by the effect of conductivity modulation.

Moreover, in accordance with silicon carbide substrate 10 according to the embodiment, third main surface 12a1 may have a root mean square roughness of not more than 10 nm. Consequently, when manufacturing a MOSFET or IGBT, a gate oxide film can have improved reliability.

Moreover, in accordance with silicon carbide substrate 10 according to the embodiment, silicon carbide epitaxial layer 12 may include an impurity capable of providing one of p type and n type. The impurity may have a concentration of not less than 1×10¹³ cm⁻³ and not more than 1×10¹⁶ cm ⁻³. Consequently, a silicon carbide semiconductor device having a high breakdown voltage can be manufactured.

Moreover, in accordance with silicon carbide substrate 10 according to the embodiment, the density of basal plane dislocations 4 existing in silicon carbide epitaxial layer 12 may be not more than 10 cm⁻³. During use of a bipolar device manufactured using this silicon carbide substrate 10, stacking faults may occur due to basal plane dislocations 4, causing degradation of forward current characteristics. By setting the density of basal plane dislocations 4 existing in silicon carbide epitaxial layer 12 to not more than 10 cm⁻³, the degradation of forward current characteristics of the bipolar device can be suppressed.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

2 stacking fault; 3 Z_{1/2} center; 4 basal plane dislocation; 5 silicon carbide crystal; 10 silicon carbide substrate; 11 silicon carbide single-crystal substrate; 11a first main surface; 11b fourth main surface; 11c1 peripheral edge; 11c2 first peripheral edge; 11d2 edge; 12 silicon carbide epitaxial layer; 12a1, 12a2 third main surface; 12b second main surface; 12c1 peripheral edge; 12c2 second peripheral edge; 12d1 boundary, edge; 12d2 boundary; 12e surface layer; A1, A2 maximum diameter; C peripheral region; L, W, W1, W2, W3 width; OF orientation flat; T1, T2, T3 thickness.

1. A method of manufacturing a silicon carbide substrate, comprising:
preparing a silicon carbide single-crystal substrate having a first main surface angled off relative to a { 0001 } plane, and a first peripheral edge provided continuously with the first main surface;
forming a silicon carbide epitaxial layer on the first main surface, the silicon carbide epitaxial layer having a second main surface in contact with the first main surface, a third main surface opposite to the second main surface, and a second peripheral edge provided continuously with each of the second main surface and the third main surface; and
removing a peripheral region including the first peripheral edge and the second peripheral edge,
the silicon carbide epitaxial layer having a thickness of not less than 50 μm in a direction perpendicular to the third main surface.

2. The method of manufacturing a silicon carbide substrate according to claim 1, wherein
after the removing a peripheral region, chemical mechanical polishing is performed on the third main surface.

3. The method of manufacturing a silicon carbide substrate according to claim 1, wherein
in the preparing a silicon carbide single-crystal substrate, a maximum diameter of the first main surface is determined in consideration of a width of the peripheral region in a direction parallel to the first main surface.

4. The method of manufacturing a silicon carbide substrate according to claim 3, wherein
assuming that an OFF angle of the first main surface is θ° and the thickness of the silicon carbide epitaxial layer is T μm, the width is not less than T/tan(θ) μm and not more than (T/tan(θ)) μm+10 mm.

5. The method of manufacturing a silicon carbide substrate according to claim 1, wherein
after the removing a peripheral region, a maximum diameter of the third main surface is not less than 100 mm.

6. The method of manufacturing a silicon carbide substrate according to claim 1, wherein
the silicon carbide epitaxial layer includes an impurity capable of providing one of p type and n type, and
the impurity has a concentration of not less than 1×10¹³ cm⁻³ and not more than 1×10¹⁶ cm⁻³.

7. The method of manufacturing a silicon carbide substrate according to claim 1, wherein
in the forming a silicon carbide epitaxial layer, a stacking fault is formed in the peripheral region, and
in the removing a peripheral region, the stacking fault is removed.

8. The method of manufacturing a silicon carbide substrate according to claim 1, wherein
in the forming a silicon carbide epitaxial layer, a silicon carbide crystal having a polytype different from a polytype of silicon carbide forming the silicon carbide epitaxial layer is formed in the peripheral region, and
in the removing a peripheral region, the silicon carbide crystal is removed.

9. A silicon carbide substrate comprising:
a silicon carbide single-crystal substrate having a first main surface; and
a silicon carbide epitaxial layer provided on the first main surface, the silicon carbide epitaxial layer having a second main surface in contact with the first main surface, a third main surface opposite to the second main surface, and a peripheral edge provided continuously with each of the second main surface and the third main surface,
the silicon carbide epitaxial layer having a thickness of not less than 50 μm in a direction perpendicular to the third main surface,
a stacking fault not being formed at a boundary between the peripheral edge and the third main surface.

10. The silicon carbide substrate according to claim 9, wherein
a silicon carbide crystal having a polytype different from a polytype of silicon carbide forming the silicon carbide epitaxial layer is not formed at the peripheral edge.

11. The silicon carbide substrate according to claim 9, wherein
a density of Z_{1/2} centers existing in the silicon carbide epitaxial layer is not more than 5×10¹¹ cm⁻³.

12. The silicon carbide substrate according to claim 9, wherein
a carrier lifetime is not less than 1 microsecond.

13. The silicon carbide substrate according to claim 9, wherein
the third main surface has a root mean square roughness of not more than 10 nm.

14. The silicon carbide substrate according to claim 9, wherein
the silicon carbide epitaxial layer includes an impurity capable of providing one of p type and n type, and
the impurity has a concentration of not less than 1×10¹³ cm⁻³ and not more than 1×10¹⁶ cm⁻³.

15. The silicon carbide substrate according to claim 9, wherein
a density of basal plane dislocations existing in the silicon carbide epitaxial layer is not more than 10 cm⁻³.
